(19) United States
(12) Patent Application Publication
(10) Pub. No.: US 2012/0325289 A1
(43) Pub. Date: Dec. 27, 2012

(54) HIGH CONCENTRATOR PHOTOVOLTAIC SOLAR MODULE

(76) Inventor: Christopher J. Deck, Maricopa, AZ (US)

(21) Appl. No.: 13/532,630

(22) Filed: Jun. 25, 2012

Related U.S. Application Data
(60) Provisional application No. 61/501,149, filed on Jun. 24, 2011.

(51) Int. Cl. H01L 31/052; H01L 31/0232

(52) U.S. Cl. 136/246; 136/259

(57) ABSTRACT

The present invention relates generally to a high concentrator photovoltaic (HCPV) solar module with a single paraboloidal reflective optic for each solar cell. The point-focus embodiments described in this present invention can achieve much higher concentration ratios in a smaller area. The truncated narrow parabaloidal reflector has a long focal length to aperture ratio, which is an important characteristic for HCPV modules. Because of the long focal lengths of these HCPV systems, the solar cell receives concentrated light under a narrow high angle of incident light. Single-cell units and arrays are disclosed. A passive cooling system for the printed circuit board that supports the photovoltaic cell is also disclosed.

### RELATED APPLICATIONS

This application claims priority to U.S. Provisional Patent Application No. 61/501,149 filed on Jun. 24, 2011 to the same inventor, entitled “REFLECTIVE OPTIC FOR HIGH CONCENTRATOR PHOTOVOLTAIC SOLAR MODULE,” which is hereby incorporated by reference as if set forth in full in this application for all purposes.

### BACKGROUND OF THE INVENTION

The present invention relates generally to a reflective optic for a high concentrator photovoltaic (HCPV) solar module.

Concentrator photovoltaic (CPV) is a strong contender as the solar device of the future. The argument has been that the cost of photovoltaic cells can be displaced by inexpensive optics and structures. With recent push of flat-plate photovoltaic towards higher efficiencies and/or lower cost, this argument seems more and more difficult to defend.

However, as research progresses towards solar cells with very high photovoltaic conversion efficiencies, due to the high cost, it is likely that CPV will eventually emerge as a necessity. Therefore, it is important that modules continue to be developed that could host these cells.

Thus, CPV systems need higher concentration ratios and lower costs. Higher concentration ratios need to have increased thermal dissipation specifications. Centralized systems (dish, central tower) rely on active cooling and must cover additional cost both in the module price and operational expense. They work best in locations where cooling water is available and inexpensive. Fresnel lens systems usually rely on passive cooling and the thermal dissipation structures represent a sizable portion of the total system cost. Accordingly, new modules and systems are needed as alternatives to these larger systems.

As far as photovoltaic concentrators are concerned, the most common configuration uses a Fresnel lens system that concentrates sunlight onto a solar cell placed in front of it. In many normal lens concentrator systems, off-axis alignment would result in a light projected outside of the solar cell (or receiver assembly) with significant power and efficiency losses. An advantage the present invention holds using parabolic point focus alignment.

U.S. Pat. No. 6,384,320 discloses a combination of a Fresnel lens focusing light into a parabolic reflector for solar heat or solar voltaic collection. The angled rays from the Fresnel lens do not appear to ray trace to the focal point of the parabolic reflector.

U.S. Pat. No. 7,688525 discloses a hybrid trough concentrator that uses a central Fresnel lens and a parabolic reflector with an off-focal point solar voltaic target, causing the solar energy to be distributed over the surface of the target.

US Published Patent Application 2009/0114213 discloses square primary and secondary reflectors for concentrating solar energy.

US Published Patent Application 2009/0188562 discloses pairs of semi-parabolic reflectors for focusing energy on both sides of a fin type solar cell.

### SUMMARY OF THE INVENTION

A high concentrator photovoltaic solar module including: a truncated narrow parabaloidal reflector having a first wider end and a second narrower end, where a focus of the parabaloidal reflector is proximate the second end; a transparent cover that does not comprise a lens closing the first end; a base assembly closing the second end; a heat sink within an enclosure in said base assembly; a printed circuit board supported on the heat sink; a photovoltaic cell mounted on the printed circuit board and interior to the reflector, where the photovoltaic cell is dimensioned and positioned to receive light reflected by the parabaloidal reflector; and metallic leads coupled to the photovoltaic cell operable to conduct electric current generated by the photovoltaic cell and to conduct heat away from the photovoltaic cell. The solar energy collector, further including a plurality of the solar energy collectors including a plurality of truncated narrow parabaloidal reflectors mounted on the passive heat sink. The solar energy collector, where the plurality of the truncated narrow parabaloidal reflectors are arranged in a rectilinear array. The solar energy collector, further including an enclosure for the plurality of the solar energy collectors. The solar energy collector, where the parabaloidal reflector is made of one of: plastic; ceramic; metal; and composite. The solar energy collector, where the parabaloidal reflector includes a plurality of pins extending from the second end and the heat sink includes a plurality of holes around the heat sink, where the plurality of pins is alignable to the plurality of holes. The solar energy collector, where the parabaloidal reflector includes a lip around the first end sized and arranged to receive the transparent cover. The solar energy collector, where the plurality of the solar energy collectors are molded as a single piece. The solar energy collector, including a plurality of solar energy collectors mounted on a heat sink on an enclosure and electrically coupled together. The solar energy collector, including an enclosure that encloses the high concentrator photovoltaic solar module between the first end of the truncated narrow parabaloidal reflector and a bottom surface of the printed circuit board. The solar energy collector, where the photovoltaic cell is located at a focal point of the truncated narrow parabaloidal reflector. The solar energy collector, where the photovoltaic cell is located displaced from a focal point of the truncated narrow parabaloidal reflector to distribute reflected light over the entire surface of the photovoltaic cell. The solar energy collector, where the enclosure includes walls and vents for passive cooling of the heat sink.

A high concentrator photovoltaic solar module including: a truncated narrow parabaloidal reflector having a first wider end and a second narrower end, where a focus of the parabaloidal reflector is proximate the second end; a transparent cover that does not comprise a lens closing the first end; a base assembly closing the second end; a heat sink within an enclosure in said base assembly; a printed circuit board supported by the heat sink; a photovoltaic cell mounted on the printed circuit board and interior to the reflector, where the photovoltaic cell is dimensioned and positioned to receive light reflected by the parabaloidal reflector; metallic leads coupled to the photovoltaic cell operable to conduct electric current generated by the photovoltaic cell and to conduct heat away from the photovoltaic cell; and vents in enclosure that allow air to flow through the heat sink to passively cool the photovoltaic cell. The solar energy collector, further including a plurality of the solar energy collectors including a plurality of truncated narrow parabaloidal reflectors that are at least one of: mounted on one heat sink; and each mounted on a discrete heat sink. The solar energy collector, where the parabaloidal reflector is made of one of a lightweight molded plastic and glass and further includes a lip at the first end for receiving the transparent cover and a plurality of pins extending axially from the second end. The solar energy collector, where the printed circuit board includes a plurality of holes sized and arranged to receive the plurality of pins. The solar energy collector, where the photovoltaic cell is located at one of: a focal point of the truncated narrow parabaloidal reflector; and displaced from a focal point of the truncated narrow parabaloidal reflector to distribute reflected light over the entire surface of the photovoltaic cell.

A high concentrator photovoltaic solar module including: a truncated narrow parabaloidal reflector molded as a single piece and having a first wider end and a second narrower end, where a focus of the parabaloidal reflector is proximate the second end; a transparent cover that does not comprise a lens closing the first end; a base assembly closing the second end; a heat sink within an enclosure in said base assembly; a printed circuit board supported on the heat sink; a photovoltaic cell mounted on the printed circuit board and interior to the reflector, where the photovoltaic cell is dimensioned and positioned to receive light reflected by the parabaloidal reflector; metallic leads coupled to the photovoltaic cell operable to conduct electric current generated by the photovoltaic cell and to conduct heat away from the photovoltaic cell; vents in the heat sink that allow air to flow through the heat sink to passively cool the photovoltaic cell; a plurality of pins extending axially from the second end of the truncated narrow parabaloidal reflector; and a plurality of holes in the heat sink sized and arranged to receive the plurality of pins.

### BRIEF DESCRIPTION OF THE DRAWINGS

Embodiments are illustrated by way of example, and not by way of limitation, in the figures of the accompanying drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments. The present invention will hereinafter be described in conjunction with the following drawing figures, wherein like numerals denote like elements, and

FIG. 1 is a perspective view illustrating an exemplary embodiment of a glass cover of a high concentrator photovoltaic solar module, according to a preferred embodiment of the present invention;

FIG. 2 is a perspective view illustrating an exemplary embodiment of a parabolic reflector, according to a preferred embodiment of the present invention;

FIG. 3 is a perspective view of an exemplary embodiment of a heat sink with an exemplary solar cell and exemplary printed circuit board be mounted to the exemplary heat sink, according to a preferred embodiment of the present invention;

FIG. 4 is a radial cross-sectional view illustrating an exemplary embodiment of a protective enclosure for the exemplary parabolic reflector and exemplary printed circuit board of FIGS. 2 and 3, according to a preferred embodiment of the present invention;

FIG. 5 is a perspective view illustrating an exemplary embodiment of a solar collection module, according to a preferred embodiment of the present invention;

FIG. 6 is a perspective view illustrating an exemplary embodiment of multiple reflectors in a module, according to a preferred embodiment of the present invention;

FIG. 7 is a perspective view illustrating an exemplary embodiment of multiple reflectors in an enclosure, according to a preferred embodiment of the present invention; and

FIG. 8 is a perspective view illustrating an exemplary embodiment of a multiple module enclosure according to a preferred embodiment of the present invention.

### DETAILED DESCRIPTION OF THE EMBODIMENTS

In the following description, reference is made to the accompanying figures which form a part hereof, and which show by way of illustration possible embodiments. As a matter of convenience, various components will be described using exemplary materials, sizes, shapes, dimensions, and the like. However, the present invention is not limited to the stated examples and other configurations are possible and within the teachings of the present disclosure. As will become apparent, changes may be made in the function and/or arrangement of any of the elements described in the disclosed exemplary embodiments without departing from the spirit and scope of this disclosure.

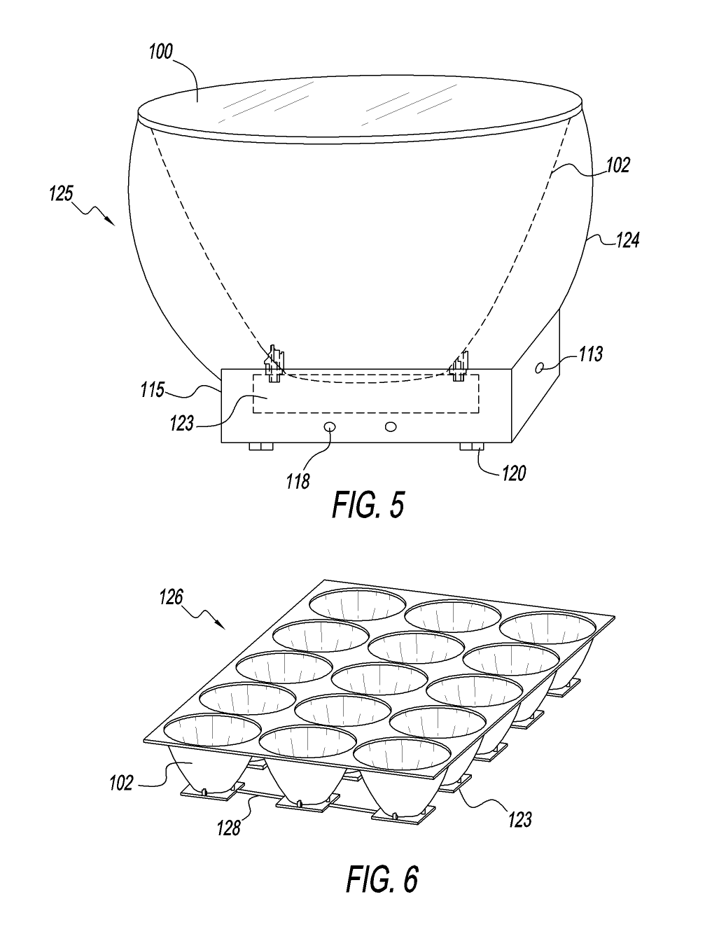

The present invention features embodiments of a reflective optic for a high concentrator photovoltaic (HCPV) solar module 125 (See FIG. 5). The design reveals many advantages that maximize the usable energy output with a much smaller footprint, or size. HCPV modules are easier to manufacture than other solar collector systems including flat-panel PV and other CPV modules having more complicated processes. As research for new triple junction cells progresses towards higher efficiencies, HCPV solar module 125 embodiments of the present invention have many advantages over flat-panel PV modules and other CPV modules in costs, footprints, and efficiencies. In short, HCPV solar module 125 embodiments have the potential of becoming the concentrating system that will make CPV cost effective.

There are many features of HCPV solar module embodiments disclosed herein, of which one, a plurality, or all features or steps may be used in any particular implementation. The following and other aspects and embodiments of an HCPV solar module may have one or more or all of the following advantages over other concentrator designs for photovoltaic cells, as well as other benefits discussed elsewhere in this document.

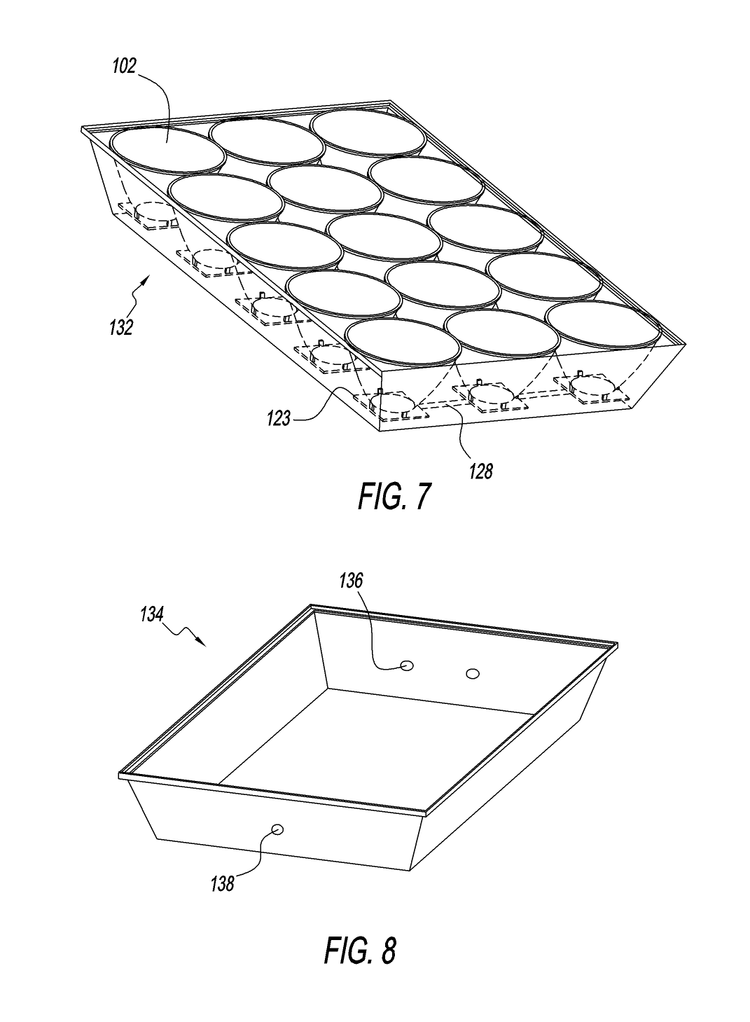

The entire module 125 can be made a singular reflector design 125 (see FIG. 5) or a multiple modular design 132 (see FIG. 7) because of the direct point-focus of each reflector, as well as its large focal parameter to aperture ratio. A narrower module necessitates less material and is easier to install, two elements that contribute to reduced costs.

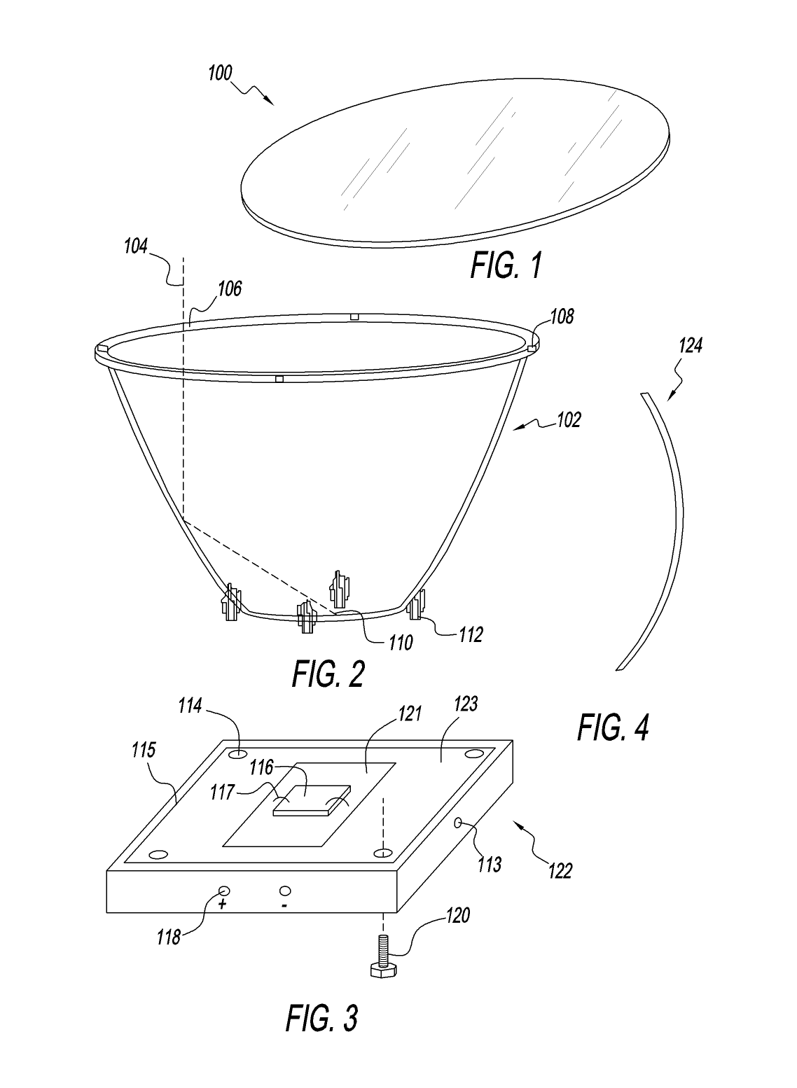

FIG. 1 is a perspective view illustrating an exemplary embodiment of a glass cover 100 of a high concentrator photovoltaic solar module 125, according to a preferred embodiment of the present invention. In a multiple-modular embodiments 132, the glass cover 100 is appropriately shaped to cover multiple modules 125 at once. Using glass, assembly and thermal match issues are minimized. The glass cover 100 is preferably at least ninety percent transparent at the wavelengths of light converted by the solar cell 116 (see FIG. 3) and more preferably transparent at the wavelengths of light converted by the solar cell 116 (see FIG. 3). No optical alignment of the glass is required. Much less degradation of the module 125 occurs during the life cycle versus other CPV modules.

FIG. 2 is a perspective view illustrating an exemplary embodiment of a parabolic reflector 102, according to a preferred embodiment of the present invention. The configuration of the present embodiment does not require a lens. Rather, The HCPV module 125 includes a parabolic reflector 102 with the receiver/solar cell 116 in focus 110. Each receiver/solar cell 116 is positioned within a parabola of revolution, or paraboloid 102 using direct-axis focal point 110 of the light 104, which is essentially of the imaging type. The parabaloidal reflector 102 has guided pins 112 for easy focal point 110 placements. Pins 112 align with and are received by mounting holes 114 see FIG. 3) to place the solar cell 116 at the focal point 110. Glass cover mounting holes 108 and lips 106 receive the glass cover 100 for easy assembly. Preferably, the light is focused in the center of the solar cell 106. In a particular embodiment, the light may be distributed over the surface of the solar cell 106.

FIG. 3 is a perspective view of an exemplary embodiment of a heat sink base assembly 122 with an exemplary solar cell 116, an exemplary printed circuit board 121, mounted to the exemplary heat sink 123, according to a preferred embodiment of the present invention. The triple junction photovoltaic cell 116 operates at a concentration ratio of about one thousand suns (1000 cm2), and is mounted on the printed circuit board 121 and electrically connected to the printed circuit board 121 with wire bonding 117. The multiple module HCPV 125 is reliant on passive cooling via the copper electrical leads 128 (see FIG. 6) from the solar cells 116 to conduct heat to the backside of the multiple module array 126 allowing the heat to easily dissipate. Because the total power focused on each solar cell 116 is small, passive cooling is enough to dissipate the heat through vents 113, through the electrical leads 117, and through heat sink 123. The heat sink 123 is situated inside an enclosure 115 and electrical connectors 118 are connected to the printed circuit board 121. Alignment holes 114 are through the heat sink 123 and enclosure 115 to allow the fasteners 120 to connect to the mounting pins 112 on the parabolic reflector 102 (see FIG. 2) which allows for easy connection and alignment of the solar cell 116 to the reflector 102.

FIG. 4 is a radial cross-sectional view illustrating an exemplary embodiment of a protective enclosure 124 for the exemplary parabolic reflector 102 and exemplary printed circuit board 121 of FIGS. 2 and 3, according to a preferred embodiment of the present invention. As can be seen in FIG. 5, enclosure 124 encircles the reflector 102 and the top portion of the base assembly 122.

FIG. 5 is a perspective view illustrating an exemplary embodiment of a solar collection module 125, according to a preferred embodiment of the present invention.

The heat sink 123 is within enclosure 115 of HCPV solar module 125. Because of optical design, HCPV solar module 125 provide for a more robust and cost effective solar energy module and system in the marketplace.

FIG. 6 is a perspective view illustrating an exemplary embodiment of multiple reflectors 125 in a multiple module array 126, according to a preferred embodiment of the present invention. Module 126 is shown without the use of the enclosure 115 shown in FIG. 3. Rather the use of enclosure 134 (see FIG. 8) is preferred. Electrical connections 128 assist in passive cooling of the module 126. The multiple module array 126 is shown as a rectilinear array, but the invention is not so limited. In a particular embodiment, all the reflectors 102 may be formed as a single piece.

FIG. 7 is a perspective view illustrating an exemplary embodiment of multiple modules 125 in an enclosure 134, according to a preferred embodiment of the present invention. Enclosure 134 has vents 138 that serve the same purpose as vents 113 to allow air to flow through and water to stay out. Enclosure 134 also has male and female electrical connectors 136 (one of two labeled).

The present invention is a reflective optic in an HCPV solar module 125. In general, this HCPV solar module 132 includes embodiments of a plurality of direct-axis portioned, parabolic reflector/cones that focus sunlight on, preferably, a triple junction photovoltaic cell 116, all mounted on printed circuit board 121 as a single concentrator unit. These units can be repeated in a closed-packed two-dimensional arrays 126 to form modules as large as a conventional flat-plate module but with a deeper profile (to minimize unused vertical space) and a narrower width (to minimize its footprint). An entire module 126 could be molded as a single piece. Triple junction solar cells 116 (see FIG. 3) (a few millimeters square) are each installed on a printed circuit board 121 in an enclosure 115 on base assembly 122. Each base assembly 122 is interconnected and soldered from the backside for connectivity purposes. In a particular embodiment, all reflectors 102 may be mounted on a single large printed circuit board.

Each receiver/solar cell 116 is positioned onto a Printed Circuit Board (PCB) 121 to avoid off-axis alignment and to create the whole HCPV module 125. By utilizing a PCB, receiver/solar cell 116 can be interconnected and soldered from the backside for connectivity purposes, eliminating the need for bulky and cumbersome wire harnesses.

Each receiver/solar cell 116 in the module 125 is connected to a parabolic cone 102 that aligns the cell 116 on a single point of focus 110 and forms a concentrator unit 125.

In a particular HCPV module embodiment, a large number of concentrator units 125 can be assembled into a single multiple module array 126 or 132 and the whole assembly 126 or 132 can operate with a Sun tracker to track the Sun with the (relative) movement of two-axis alignment.

The entire HCPV module 132 is achieved by engineering and manufacturing a single or whole group of parabolic cones 102 and putting them in multiple rows to form an array 126. One reflector 102 is assembled right next to the other on a grid. Ray-tracing simulation gives the location of each receiver/solar cell 116 which is at the focal point 110 located just below the reflector/parabolic cone 102. The focal lengths of the parabolic reflectors 102 and their relative positions are adjusted in such a way that each cell 116 and its energy output are to be maximized by this design configuration with a contiguous reflective surface. In particular embodiments, the cell 116 may be slightly above or below the focal point 110 of the reflector 102, in order to spread the incident light 104 over the whole top surface of the cell 116.

Such a concentrator unit array 132 would offer three (3) advantages: (1) alignment between the solar cell 116 and the optical elements 102 would be facilitated by features on both the package and on the reflector; (2) the solar cell 116 would be protected against moisture and other environmental factors; and (3) each module 125 could be tested individually before being integrated in the multiple module array 132.

HCPV modules may include: (1) individual cones; (2) rows of several cones; and/or (3) a single molded piece. Moreover, it is possible to add some additional features on the backside of the parabolic reflectors and/or PCB board; they would be outside the optical path for minimal impact to the optical efficiency. Examples of such additional features are

heat sinks and fixtures for the receptors/solar cells and their electrical connections.

Compared again to a conventional module where lenses and secondary reflectors are being used (most CPV modules and linear trough versions), the point-focus embodiments described in the present invention can achieve much higher concentration ratios in a smaller area. Referring back to FIG. 2 the modules of the present invention have a long focal length to aperture ratio, which is an important characteristic for HCPV modules. Because of the long focal lengths of the HCPV systems 125, 126, 132 of the present invention, the solar cell 116 receives concentrated light under a narrow high angle of incident light.

It will be understood that embodiments are not limited to the specific components disclosed herein, as various components consistent with the intended operation of an HCPV solar module 125, 126, and 132 may be utilized. Accordingly, for example, although particular components and so forth, are disclosed, such components may comprise any shape, size, style, type, model, version, class, grade, measurement, concentration, material, weight, quantity, and/or the like consistent with the intended operation of an HCPV solar module 125, 126, and 132. Embodiments are not limited to uses of any specific components, provided that the components selected are consistent with the intended operation of an HCPV solar module 125, 126, and 132.

Accordingly, the components defining any HCPV solar module 125, 126, and 132 embodiment may be formed of various materials or combinations thereof that can readily be formed into shaped objects provided that the components selected are consistent with the intended operation of an apparatus for collecting solar energy. For example, the components may be formed of: rubbers (synthetic and/or natural) and/or other like materials; glass, fiberglass, carbon-fiber, aramid-fiber, any combination thereof, and/or other like materials; polymers such as thermoplastics (such as ABS, Fluoropolymers, Polyacetal, Polyamide; Polycarbonate, Polyethylene, Polysulfone, and/or the like), thermosets (such as Epoxy, Phenolic Resin, Polyimide, Polyurethane, Silicone, and/or the like), various combination thereof, and/or other like materials; composites and/or other like materials; metals, such as zinc, magnesium, titanium, copper, iron, steel, carbon steel, alloy steel, tool steel, stainless steel, spring steel, aluminum, various combination thereof, and/or other like materials; alloys, such as aluminum alloy, titanium alloy, magnesium alloy, copper alloy, various combination thereof, and/or other like materials; any other suitable material; and/or various combination thereof. Essentially, any material that can maintain its functional shape over the operational temperature range will suffice.

Various HCPV solar module embodiments 125, 126, and 132 may be manufactured using conventional procedures as added to and improved upon through the procedures described here. Some components defining embodiments may be manufactured simultaneously and integrally joined with one another, while other components may be purchased pre-manufactured or manufactured separately and then assembled with the integral components.

Manufacture of these components separately or simultaneously may involve extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled with one another in any manner, such as with adhesive, a weld, a solder joint, a fastener (e.g. a bolt, a nut, a screw, a rivet, a pin, and/or the like), wiring, any combination thereof, and/or the like for example, depending on, among other considerations, the particular material forming the components.

Thus, for the exemplary purposes of this disclosure, a parabolic cone 102 embodiment may be used in a singular cone configuration 125 or may be a multiple cone configuration 126 and 132 manufactured via injection molding. Injection molding offers the best solution for product reliability and lower manufacturing costs. An entire HCPV module 126, and 132 can then achieved by molding a whole group of parabolic cones together into a single module. One reflector 102 is molded right next to the other on a grid. Ray-tracing simulation gives the location of each receiver/solar cell 116 which is at the focal point 110 located just below the reflector/parabolic cone 102. A complete HCPV module 126 or 132 may be made of many rows and columns of unit concentrators within an enclosure with vents 138 and power connectors 136 (see FIG. 8).

FIG. 8 is a perspective view illustrating an exemplary embodiment of a multiple module enclosure 134 according to a preferred embodiment of the present invention. The enclosure 134 protects the electronics, provides venting, conducts heat and radiates and/or conducts it to the atmosphere, and provides power connectors 136 (one of two labeled).

It will be understood that the assembly or installation of embodiments of an HCPV solar module are not limited to the specific order of steps as disclosed in this document. Any steps or sequence of steps of the assembly or installation of embodiments indicated herein are given as examples of possible steps or sequence of steps and not as limitations, since various assembly and installation processes and sequences of steps may be used.

The aspects and embodiments listed here, and many others, will become readily apparent to those of ordinary skill in the art from this disclosure. Those of ordinary skill in the art will readily understand the versatility with which this disclosure may be applied.

Embodiments of an HCPV solar module 125, 126, and 132 are useful in a variety of applications.

In places where the description above refers to particular embodiments of an HCPV solar module 125, 126, and 132, it should be readily apparent that a number of modifications may be made without departing from the spirit thereof. The presently disclosed aspects and embodiments are, therefore, to be considered in all respects as illustrative and not restrictive.

What I claim is:

1. A high concentrator photovoltaic solar module comprising:
a. a truncated narrow parabaloidal reflector having a first wider end and a second narrower end, wherein a focus of the parabaloidal reflector is proximate said second end;
b. a transparent cover that does not comprise a lens closing the first end;
c. a base assembly closing the second end;
d. a heat sink within an enclosure in said base assembly;
e. a printed circuit board supported on said heat sink;
f. a photovoltaic cell mounted on said printed circuit board and interior to said reflector, wherein said photovoltaic cell is dimensioned and positioned to receive light reflected by said parabaloidal reflector; and
g. metallic leads coupled to said photovoltaic cell operable to conduct electric current generated by said photovoltaic cell and to conduct heat away from said photovoltaic cell.

2. The high concentrator photovoltaic solar module of claim 1, further comprising a plurality of said solar energy collectors of claim 1 comprising a plurality of truncated narrow parabaloidal reflectors mounted on said passive heat sink.

3. The high concentrator photovoltaic solar module of claim 2, wherein said plurality of said truncated narrow parabaloidal reflectors are arranged in a rectilinear array.

4. The high concentrator photovoltaic solar module of claim 2, further comprising an enclosure for said plurality of said solar energy collectors.

5. The high concentrator photovoltaic solar module of claim 1, wherein said parabaloidal reflector is made of one of:
a. plastic;
b. ceramic;
c. metal;
d. glass; and
e. composite.

6. The high concentrator photovoltaic solar module of claim 1, wherein said parabaloidal reflector comprises a plurality of pins extending from said second end and said heat sink comprises a plurality of holes around said heat sink, wherein said plurality of pins is alignable to said plurality of holes.

7. The high concentrator photovoltaic solar module of claim 1, wherein said parabaloidal reflector comprises a lip around said first end sized and arranged to receive said transparent cover.

8. The high concentrator photovoltaic solar module of claim 2, wherein said plurality of said solar energy collectors are molded as a single piece.

9. The high concentrator photovoltaic solar module of claim 1, comprising a plurality of solar energy collectors mounted on a heat sink on an enclosure and electrically coupled together.

10. The high concentrator photovoltaic solar module of claim 1, comprising an enclosure that encloses said high concentrator photovoltaic solar module between said first end of said truncated narrow parabaloidal reflector and a bottom surface of said printed circuit board.

11. The high concentrator photovoltaic solar module of claim 1, wherein said photovoltaic cell is located at a focal point of said truncated narrow parabaloidal reflector.

12. The high concentrator photovoltaic solar module of claim 1, wherein said photovoltaic cell is located displaced from a focal point of said truncated narrow parabaloidal reflector to distribute reflected light over the entire surface of said photovoltaic cell.

13. The high concentrator photovoltaic solar module of claim 9, wherein said enclosure comprises walls with vents.

14. The high concentrator photovoltaic solar module of claim 1, wherein said heat sink comprises an interface with vents in said enclosure for passive cooling.

15. A high concentrator photovoltaic solar module comprising:
a. a truncated narrow parabaloidal reflector having a first wider end and a second narrower end, wherein a focus of the parabaloidal reflector is proximate said second end;
b. a transparent cover that does not comprise a lens closing the first end;
c. a base assembly closing the second end and having an enclosure;
d. a heat sink within said enclosure in said base assembly;
e. a printed circuit board supported by said heat sink;
f. a photovoltaic cell mounted on said printed circuit board and interior to said reflector, wherein said photovoltaic cell is dimensioned and positioned to receive light reflected by said parabaloidal reflector;
g. metallic leads coupled to said photovoltaic cell operable to conduct electric current generated by said photovoltaic cell and to conduct heat away from said photovoltaic cell; and
h. vents in said enclosure that allow air to flow through said heat sink to passively cool said photovoltaic cell.

16. The high concentrator photovoltaic solar module of claim 15, further comprising a plurality of said solar energy collectors of claim 15 comprising a plurality of truncated narrow parabaloidal reflectors that are at least one of:
a. mounted on one base assembly; and
b. each mounted on a discrete base assembly.

17. The high concentrator photovoltaic solar module of claim 15, wherein said parabaloidal reflector is made of one of a lightweight molded plastic and glass and further comprises a lip at said first end for receiving said transparent cover and a plurality of pins extending axially from said second end.

18. The high concentrator photovoltaic solar module of claim 17, wherein said printed circuit board comprises a plurality of holes sized and arranged to receive said plurality of pins.

19. The high concentrator photovoltaic solar module of claim 15, wherein said photovoltaic cell is located at one of:
a. a focal point of said truncated narrow parabaloidal reflector; and
b. displaced from a focal point of said truncated narrow parabaloidal reflector to distribute reflected light over the entire surface of said photovoltaic cell.

20. A high concentrator photovoltaic solar module comprising:
a. a truncated narrow parabaloidal reflector molded as a single piece and having a first wider end and a second narrower end, wherein a focus of the parabaloidal reflector is proximate said second end;
b. a transparent cover that does not comprise a lens closing the first end;
c. a base assembly closing the second end and having an enclosure;
d, a heat sink within said enclosure in said base assembly;
e. a printed circuit board supported on said heat sink;
f. a photovoltaic cell mounted on said printed circuit board and interior to said reflector, wherein said photovoltaic cell is dimensioned and positioned to receive light reflected by said parabaloidal reflector;
g. metallic leads coupled to said photovoltaic cell operable to conduct electric current generated by said photovoltaic cell and to conduct heat away from said photovoltaic cell;
h. vents in said heat sink that allow air to flow through said heat sink to passively cool said photovoltaic cell;
i. a plurality of pins extending axially from said second end of said truncated narrow parabaloidal reflector; and
j. a plurality of holes in said heat sink sized and arranged to receive said plurality of pins.
